(19) United States
(12) Patent Application Publication
(10) Pub. No.: US 2011/0186124 A1
(43) Pub. Date: Aug. 4, 2011

(54) ELECTRICALLY CONDUCTIVE ZINC OXIDE LAYERED FILM AND PHOTOELECTRIC CONVERSION DEVICE COMPRISING THE SAME

(75) Inventors: Ryouko AGUI, Ashigarakami-gun (JP); Tetsuo KAWANO, Ashigarakami-gun (JP)

(73) Assignee: FUJIFILM CORPORATION, Tokyo (JP)

(21) Appl. No.: 13/016,697

(22) Filed: Jan. 28, 2011

(30) Foreign Application Priority Data
Jan. 29, 2010 (JP) 2010-019049

(51) Int. Cl. H01L 31/0224

(52) U.S. Cl. 136/256

(57) ABSTRACT

An electrically conductive zinc oxide layered film having been formed on a substrate, at least a surface of the substrate being electrically non-conductive, comprises: (i) an electrically conductive zinc oxide fine particle layer, which is formed on the electrically non-conductive surface of the substrate, and which comprises at least one kind of a plurality of fine particles containing electrically conductive zinc oxide as a principal ingredient, and (ii) an electrically conductive zinc oxide thin film layer, which is formed on the electrically conductive zinc oxide fine particle layer.

### BACKGROUND OF THE INVENTION

1. Field of the Invention

This invention relates to an electrically conductive zinc oxide layered film adapted for use as a transparent electrode layer. This invention also relates to a photoelectric conversion device comprising the electrically conductive zinc oxide layered film.

2. Description of the Related Art

Photoelectric conversion devices comprising a photoelectric conversion layer and electrodes electrically connected to the photoelectric conversion layer have heretofore been used in use applications, such as solar cells. Heretofore, as the solar cells, Si type solar cells utilizing bulk single crystalline Si or polycrystalline Si, or thin film amorphous Si have been most popular. Recently, research and development have been conducted on compound semiconductor type solar cells that do not depend upon Si. As the compound semiconductor type solar cells, there have been known bulk types, such as GaAs types, and thin film types, such as CIS or CIGS types which are constituted of a Group-Ib element, a Group-IIIb element, and a Group-VIb element. The CI(G)S types are the compound semiconductors that are represented by the general formula of Cu_{1-z}In₁₋ₓGaₓSe_{2-y}S_{y}, wherein 0≦x≦1, 0≦y≦2, and 0≦z≦1. In cases where x=0, the compound semiconductors are of the CIGS types. In cases where x>0, the compound semiconductors are of the CIS types. In this specification, both the CIS types and the CIGS types are often referred to as the CI(G)S types.

In the cases of the thin film types of the photoelectric conversion devices, such as the CI(G)S types, ordinarily, a transparent conductive layer (a transparent electrode) is formed on a light absorbing surface side of a photoelectric conversion layer with a buffer layer intervening between the transparent conductive layer and the photoelectric conversion layer.

As the transparent conductive layer, an electrically conductive zinc oxide film obtained with processing, wherein zinc oxide is doped with a dopant element having a higher valence number of ion than zinc, has attracted particular attention for abundance of resources and a lower cost than ITO (indium tin oxide), which is popular currently.

As a technique for forming the electrically conductive zinc oxide film, a liquid phase technique is preferable for a low cost and possibility of production of a large-area film. Examples of the liquid phase techniques include a chemical bath deposition technique (CBD technique) and an electrolytic deposition technique (electrodeposition technique). As the technique for forming the electrically conductive zinc oxide film, it is preferable to use the electrodeposition technique, which enables the doping of the dopant element in a high concentration. However, in the cases of the electrodeposition technique, it is necessary for an underlayer, on which the electrically conductive zinc oxide film is to be formed, to function as an electrode. Accordingly, in cases where the underlayer is an electrically non-conductive layer, it is necessary that the electrodeposition technique is applied after an initial layer has been formed previously by use of a film forming technique other than the electrodeposition technique.

Each of Japanese Unexamined Patent Publication No. 2002-020884 and Japanese Patent No. 3445293 discloses a method of forming an electrically conductive zinc oxide film, wherein an initial layer of an electrically conductive zinc oxide layer is formed with sputtering film formation, and wherein an electrically conductive zinc oxide film is thereafter formed with an electrodeposition technique. However, for the formation of the initial layer, as in the cases of the electrically conductive zinc oxide film, since the liquid phase technique is preferable for a low cost and the possibility of production of a large-area film, it is not preferable to use vacuum film forming processing, such as the sputtering technique.

The CBD technique described above is the technique that enables the formation of the zinc oxide film on an electrically non-conductive underlayer. Therefore, the CBD technique is appropriate as the technique for forming an initial layer for the electrodeposition technique. However, since zinc oxide is a wurtzite crystal, in cases where a morphology control agent (such as an organic molecule) for growth control of a specific crystal face, or the like, is not used particularly in the CBD technique, a growth rate in the c-axis direction of the crystal is ordinarily quick, and the crystal is apt to grow in a rod-like shape. As a result, large rod-shaped crystals deposit, and a film is not formed. Even though a film is formed, a film structure, wherein a plurality of fine rod-shaped crystals stand side by side with a spacing being left therebetween, is obtained. It is thus not always possible to appropriately cover the underlayer.

As methods of controlling the crystal growth and forming a zinc oxide film which appropriately covers an underlayer, there have been proposed the methods, wherein a plurality of metal fine particles are imparted to the underlayer, and wherein a zinc oxide film is then formed with the CBD technique. In Japanese Patent No. 4081625, a method is disclosed, wherein an underlayer is catalyzed with an activator containing Ag ions, and wherein a zinc oxide film is then formed by use of a zinc oxide deposition solution. For example, in paragraph 0026 of Japanese Unexamined Patent Publication No. 2002-020884, a method is described, wherein an underlayer is catalyzed with an activator containing Ag ions, wherein zinc oxide is then deposited with an electroless technique, and wherein energizing processing is performed in a zinc oxide deposition solution by utilizing the thus obtained ZnO deposit as a cathode and utilizing a zinc plate as an anode, whereby ZnO is grown. Similar techniques are also described in J. Katayama, “Application of ZnO Prepared with Soft Solution Processing and Cu₂O Semiconductor Thin Film to Optoelectronics”, Ritsumeikan University doctoral thesis, 2004; and H. Ishizaki et al., “Influence of (CH₃)₂NHBH₃ Concentration on Electrical Properties of Electrochemically Grown ZnO Films”, Journal of The Electrochemical Society, Vol. 148, Issue 8, pp. C540-0543, 2001.

However, in cases where the electrically conductive zinc oxide film is formed ultimately by performing the steps up to the electrodeposition technique in accordance with each of the methods described in Japanese Unexamined Patent Publication No. 2002-20884; J. Katayama, “Application of ZnO Prepared with Soft Solution Processing and Cu₂O Semiconductor Thin Film to Optoelectronics”, Ritsumeikan University doctoral thesis, 2004; and H. Ishizaki et al., “Influence of (CH₃)₂NHBH₃ Concentration on Electrical Properties of Electrochemically Grown ZnO Films”, Journal of The Electrochemical Society, Vol. 148, Issue 8, pp. C540-0543, 2001, a specific resistance value of the obtained electrically conductive zinc oxide film is as high as approximately 7.8×10⁻³ Ω·cm, which corresponds to a sheet resistance value of as high as approximately 200Ω/□, and a resistance value satisfactory for the electrode layer is not obtained. (The resistance value described above is cited from J. Katayama, “Application of ZnO Prepared with Soft Solution Processing and Cu₂O Semiconductor Thin Film to Optoelectronics”, Ritsumeikan University doctoral thesis, 2004.) Also, in cases where the metal layer is used as the underlayer for the transparent conductive layer, since the metal layer affects a band gap, there is the risk that the device characteristics will become bad.

### SUMMARY OF THE INVENTION

The primary object of the present invention is to provide an electrically conductive zinc oxide layered film, which is formed on an electrically non-conductive underlayer with a liquid phase technique such that a metal layer need not be formed, which appropriately covers the electrically non-conductive underlayer, and which is appropriate as an initial layer for an electrodeposition technique.

Another object of the present invention is to provide an electrically conductive zinc oxide layered film, which is obtained by use of the aforesaid electrically conductive zinc oxide layered film, and which has a low resistance value.

The present invention provides an electrically conductive zinc oxide layered film having been formed on a substrate, at least a surface of the substrate being electrically non-conductive, the electrically conductive zinc oxide layered film comprising:

i) an electrically conductive zinc oxide fine particle layer, which is formed on the electrically non-conductive surface of the substrate, and which comprises at least one kind of a plurality of fine particles containing electrically conductive zinc oxide as a principal ingredient, and

ii) an electrically conductive zinc oxide thin film layer, which is formed on the electrically conductive zinc oxide fine particle layer.

The term “electrically conductive zinc oxide” as used herein means the zinc oxide having been subjected to processing for increasing carrier electrons by introducing a dopant, such as boron, gallium, or aluminum, into the zinc oxide.

Also, the term “at least a surface being electrically non-conductive” as used herein means that the sheet resistance value of the surface is equal to at least 1×10¹²Ω/□. The term “substrate, at least a surface thereof being electrically non-conductive” as used herein means the substrate or a layer comprising the substrate and at least one thin film stacked on the substrate, at least the surface of the substrate or the laminate being electrically non-conductive. As will be described later, constituent elements of a photoelectric conversion device in accordance with the present invention include a “substrate.” The term “substrate” as used herein for the photoelectric conversion device in accordance with the present invention has the ordinary meaning of the “substrate.” In the cases of the photoelectric conversion device, a layer comprising the substrate and a plurality of layers, which range to a buffer layer and which are stacked on the substrate, or a layer comprising the aforesaid layer and a high-resistance window layer, which is free from a dopant and which is stacked on the aforesaid layer, corresponds to the term “substrate, at least a surface thereof being electrically non-conductive” as used herein for the electrically conductive zinc oxide layered film in accordance with the present invention.

Further, the term “principal ingredient” as used herein means the ingredient whose content is equal to at least 80% by mass.

Furthermore, the term “fine particles” as used herein means the particles having a mean particle diameter of at most 100 nm. In the electrically conductive zinc oxide layered film in accordance with the present invention, the mean particle diameter of the fine particles should be preferably selected within the range of 1 nm to 50 nm.

The term “mean particle diameter” as used herein means the mean particle diameter calculated from a transmission electron microscope image (TEM image). Specifically, the fine particles having been dispersed sufficiently are observed with the TEM, and fine particle image file information is recorded. With respect to the fine particle image file information having been obtained, analysis is made for each particle by use of an image analysis type of particle size distribution analysis software (Mac-View, Ver. 3, manufactured by Mountech Co., Ltd.). Summation is then made with respect to 50 pieces of the fine particles having been selected at random, and the mean particle diameter is thus calculated. In cases where the particles are aspherical particles, the mean particle diameter of the aspherical particles is represented by the sphere-equivalent mean particle diameter.

The electrically conductive zinc oxide layered film in accordance with the present invention should preferably be modified such that the electrically conductive zinc oxide thin film layer, which is formed on the electrically conductive zinc oxide fine particle layer, is taken as a first electrically conductive zinc oxide thin film layer, and

the electrically conductive zinc oxide layered film further comprises a second electrically conductive zinc oxide thin film layer, which is formed with an electrolytic deposition technique on the first electrically conductive zinc oxide thin film layer.

Also, the electrically conductive zinc oxide layered film in accordance with the present invention should preferably be modified such that the plurality of the fine particles constituting the electrically conductive zinc oxide fine particle layer contains, as a principal ingredient, at least one of the electrically conductive zinc oxides selected from the group consisting of boron-doped zinc oxide, aluminum-doped zinc oxide, and gallium-doped zinc oxide.

Further, the electrically conductive zinc oxide layered film in accordance with the present invention should preferably be modified such that the electrically conductive zinc oxide thin film layer, which is formed on the electrically conductive zinc oxide fine particle layer, contains boron-doped zinc oxide as a principal ingredient. Furthermore, the electrically conductive zinc oxide layered film in accordance with the present invention should preferably be modified such that the second electrically conductive zinc oxide thin film layer contains boron-doped zinc oxide as a principal ingredient.

Also, the electrically conductive zinc oxide layered film in accordance with the present invention should preferably be modified such that a mean layer thickness d1 (nm) of the electrically conductive zinc oxide fine particle layer, a mean layer thickness d2 (nm) of the first electrically conductive zinc oxide thin film layer, which is formed on the electrically conductive zinc oxide fine particle layer, and a mean layer thickness d3 (nm) of the second electrically conductive zinc oxide thin film layer satisfy the conditions of Formula (1) and Formula (2):

100≦d1+d2+d3(nm)≦2000 (1)

d1≦d2≦d3 (2)

Further, the electrically conductive zinc oxide layered film in accordance with the present invention should preferably be modified such that the electrically conductive zinc oxide layered film has a sheet resistance value of as low as at most 4.0×10¹⁰Ω/□.

The present invention also provides a photoelectric conversion device, comprising a bottom electrode layer, a photoelectric conversion semiconductor layer, a buffer layer, and a transparent conductive layer, which are stacked in this order on a substrate,

wherein the transparent conductive layer is formed on the buffer layer, and

the transparent conductive layer comprises:

i) an electrically conductive zinc oxide fine particle layer, which is formed on a surface of the buffer layer or on a surface of an electrically non-conductive thin film layer formed on the buffer layer, and which comprises at least one kind of a plurality of fine particles containing electrically conductive zinc oxide as a principal ingredient, and

ii) an electrically conductive zinc oxide thin film layer, which is formed on the electrically conductive zinc oxide fine particle layer.

Specifically, in the photoelectric conversion device in accordance with the present invention, the transparent conductive layer is constituted of the aforesaid electrically conductive zinc oxide layered film in accordance with the present invention.

The term “transparent” as used herein means that the transmittance with respect to the sunlight is equal to at least 70%.

The photoelectric conversion device in accordance with the present invention should preferably be modified such that the buffer layer contains a metal sulfide containing at least one of the metal elements selected from the group consisting of Cd, Zn, Sn, and In.

The photoelectric conversion device in accordance with the present invention is applicable appropriately in cases where a principal ingredient of the photoelectric conversion semiconductor layer is at least one compound semiconductor having a chalcopyrite structure. In such cases, the principal ingredient of the photoelectric conversion semiconductor layer may be at least one compound semiconductor comprising:

at least one of the Group-Ib elements selected from the group consisting of Cu and Ag,

at least one of the Group-IIIb elements selected from the group consisting of Al, Ga, and In, and

at least one of the Group-VIb elements selected from the group consisting of S, Se, and Te.

Also, the photoelectric conversion device in accordance with the present invention should preferably be modified such that the substrate is an anodized substrate selected from the group consisting of:

an anodized substrate comprising: (a) an Al base material containing Al as a principal ingredient, and (b) an anodic oxide film containing Al₂O₃ as a principal ingredient, the anodic oxide film being formed on at least one surface side of the Al base material,

an anodized substrate comprising: (a) a composite base material which is constituted of an Fe material containing Fe as a principal ingredient, and an Al material containing Al as a principal ingredient, the Al material being composited on at least one surface side of the Fe material, and (b) an anodic oxide film containing Al₂O₃ as a principal ingredient, the anodic oxide film being formed on at least one surface side of the composite base material, and

an anodized substrate comprising: (a) a base material which is constituted of an Fe material containing Fe as a principal ingredient, and an Al film containing Al as a principal ingredient, the Al film being formed on at least one surface side of the Fe material, and (b) an anodic oxide film containing Al₂O₃ as a principal ingredient, the anodic oxide film being formed on at least one surface side of the base material.

As described above, the electrically conductive zinc oxide layered film in accordance with the present invention is formed on the substrate, at least the surface of the substrate being electrically non-conductive, and comprises:

i) the electrically conductive zinc oxide fine particle layer, which is formed on the electrically non-conductive surface of the substrate, and which comprises at least one kind of the plurality of the fine particles containing electrically conductive zinc oxide as a principal ingredient, and

ii) the electrically conductive zinc oxide thin film layer, which is formed on the electrically conductive zinc oxide fine particle layer that acts as an underlayer.

The electrically conductive zinc oxide thin film (layered film) having the constitution described above enables the film formation to be performed with the liquid phase technique on the substrate, at least the surface of the substrate being electrically non-conductive, such that a metal layer need not be formed. The electrically conductive zinc oxide thin film (layered film) having thus been formed appropriately covers the underlayer. Therefore, with the electrically conductive zinc oxide thin film (layered film) in accordance with the present invention, the electrically conductive zinc oxide thin film (layered film) that has a low resistance and that is thus appropriate as the transparent conductive layer (transparent electrode) is formed with the electrodeposition technique even on the substrate whose surface is electrically non-conductive, such as a layer provided with an electrically non-conductive layer, e.g. an electrical insulator layer, at the top surface.

### BRIEF DESCRIPTION OF THE DRAWINGS

FIG. 1 is a schematic sectional view showing a constitution of an embodiment of the electrically conductive zinc oxide layered film in accordance with the present invention,

FIGS. 2A to 2D are schematic sectional views showing a process for producing the embodiment of the electrically conductive zinc oxide layered film in accordance with the present invention,

FIG. 3 is a schematic sectional view showing a constitution of an embodiment of the photoelectric conversion device in accordance with the present invention,

FIGS. 4A to 4E are schematic sectional views showing a process for producing the embodiment of the photoelectric conversion device in accordance with the present invention,

FIG. 5A is a schematic sectional view showing an example of a constitution of an anodized substrate,

FIG. 5B is a schematic sectional view showing a different example of a constitution of an anodized substrate, and

FIG. 6 is a perspective view showing a method of producing an anodized substrate.

### DESCRIPTION OF THE PREFERRED EMBODIMENTS

The present invention will hereinbelow be described in further detail with reference to the accompanying drawings.

### [Electrically Conductive Zinc Oxide Layered Film]

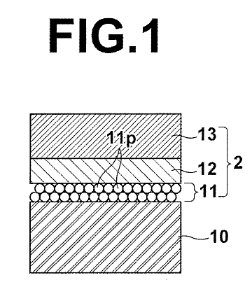

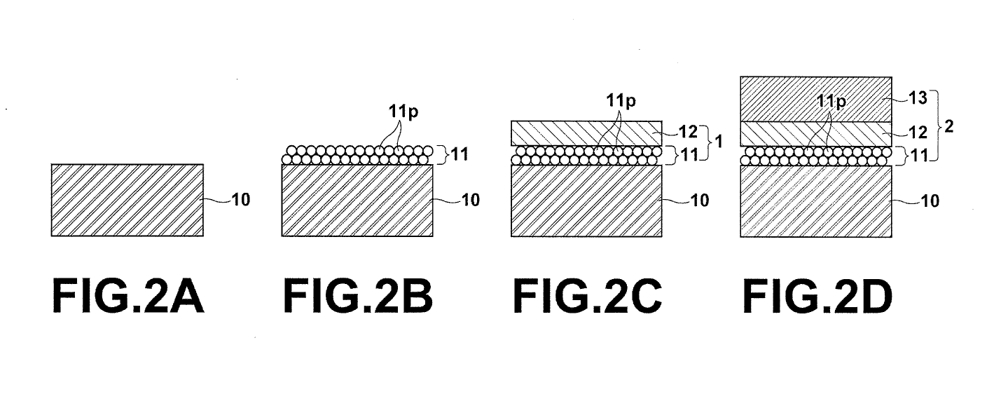

An embodiment of the electrically conductive zinc oxide layered film in accordance with the present invention will be described hereinbelow with reference to FIG. 1 and FIGS. 2A to 2D. FIG. 1 is a schematic sectional view showing a constitution of an embodiment of the electrically conductive zinc oxide layered film in accordance with the present invention. FIGS. 2A to 2D are schematic sectional views showing a process for producing the embodiment of the electrically conductive zinc oxide layered film shown in FIG. 1. For clearness, the scale of each of the constituent elements is appropriately varied from the actual scale.

In this embodiment, since the respective layers containing the electrically conductive zinc oxide as a principal ingredient are stacked one upon another, the electrically conductive zinc oxide thin film having thus been produced is referred to as the “layered film.” In the embodiment of the electrically conductive zinc oxide layered film in accordance with the present invention, each of the layers stacked one upon another contains the electrically conductive zinc oxide as a principal ingredient. Since each of the stacked layers is formed with the corresponding underlayer acting as a starting point of crystal growth, it often occurs that the boundary between the adjacent layers is not recognized. In this invention, the produced film is referred to as the “layered film” regardless of whether the boundary between the layers is present or absent. However, in cases where the principal ingredient and the film thickness of the layered film are taken into consideration, the layered film can be regarded as a single thin film.

With reference to FIG. 1, an electrically conductive zinc oxide layered film 1 (as illustrated in FIG. 2C) is formed on a substrate 10, at least the surface of the substrate 10 being electrically non-conductive, and comprises: (i) an electrically conductive zinc oxide fine particle layer 11, which is formed on the electrically non-conductive surface of the substrate 10, and which comprises at least one kind of a plurality of fine particles 11p, 11p, . . . containing electrically conductive zinc oxide as a principal ingredient, and (ii) a first electrically conductive zinc oxide thin film layer 12, which is formed on the electrically conductive zinc oxide fine particle layer 11 that acts as an underlayer.

The electrically conductive zinc oxide layered film 1 may be formed with a process as illustrated in FIGS. 2A to 2D. Specifically, as illustrated in FIG. 2A, the substrate 10, at least the surface of the substrate 10 being electrically non-conductive, is prepared. Also, as illustrated in FIG. 2B, the underlayer 11, which comprises the plurality of the electrically conductive zinc oxide fine particles 11p, 11p, . . . , is formed on the surface of the substrate 10 by use of a coating technique. Further, as illustrated in FIG. 2C, the first electrically conductive zinc oxide thin film layer 12 is formed on the underlayer 11 by use of the chemical bath deposition technique (CBD technique).

As described above under “Description of the Related Art,” in cases where the underlayer is electrically non-conductive, even though it is intended to form a zinc oxide layer directly on the underlayer with the CBD technique, it is not possible to appropriately control the crystal growth, and large crystals deposit. Therefore, it is not always possible to obtain a film that appropriately covers the underlayer.

The CBD technique is the technique wherein a crystal is deposited on a substrate at an adequate rate in a stable environment by using a metal ion solution, which has a concentration and pH such that supersaturation conditions are obtained through equilibrium as represented by the general formula [M(L)ᵢ]^{m+} [symbol] Mⁿ⁺+iL (wherein M represents a metal element, L represents a ligand, and each of m, n, and i represents a positive number), as a reaction mixture, and forming a complex of the metal ion M. As the technique for depositing a plurality of fine particles on a substrate with the CBD technique, there may be mentioned a technique described in, for example, G. Hodes, “Semiconductor and ceramic nanoparticle films deposited by chemical bath deposition”, Physical Chemistry Chemical Physics, Vol. 9, pp. 2181-2196, 2007.

In cases where ZnO is formed directly on a substrate by use of the CBD technique, the problems often occur in that the density of nucleus generation is not sufficient and in that a film sufficiently covering the underlayer is not formed. The problems occur due to the phenomenon in which the number of the nuclei generated initially is small. Specifically, it is presumed that the state of the initial nuclei markedly affects the texture of the zinc oxide thin film which grows subsequently. Therefore, important factors are the presence or absence of the initial nuclei or a substance, which is capable of acting as a catalyst for the formation of the initial nuclei, on the underlayer surface, and the in-plane density of the initial nuclei or the aforesaid substance on the underlayer surface.

With the method disclosed in Japanese Patent No. 4081625, a metal fine particle layer having good electrically conductive characteristics is formed on an electrically non-conductive substrate by use of catalyzing treatment, and thereafter an electrically conductive zinc oxide thin film is formed. However, the inventors presume that, with the catalyzing treatment, it is not always possible to arrange the metal fine particles at a high density in the metal fine particle layer, and it is not always possible to sufficiently obtain the starting points for the crystal growth in the film formation with the CBD technique.

As described above, in this embodiment, before the film formation of the electrically conductive zinc oxide thin film layer is performed with the CBD technique, the underlayer comprising the fine particles (hereinbelow referred to as the electrically conductive zinc oxide fine particles) containing electrically conductive zinc oxide as the principal ingredient is formed with the coating technique. As it will be indicated later in Examples in accordance with the present invention, with the process for producing this embodiment of the electrically conductive zinc oxide layered film, the crystal growth of the metal oxide layer is controlled appropriately, and the electrically conductive zinc oxide thin film layer that covers the underlayer approximately closely is formed. Therefore, though it has not been clarified sufficiently, it is presumed that the electrically conductive zinc oxide fine particles of the underlayer have the effects of the initial nuclei, which act as the starting points of the crystal growth, or the catalyst for the crystal growth. It is also presumed that the density of the fine particles in the underlayer is a high density sufficient for the formation of the electrically conductive zinc oxide thin film layer.

Further, the inventors presume that the fine particle layer has the effects of enhancing the spontaneous nucleus generation in the reaction mixture, and the like.

Furthermore, in the cases of the application as the transparent conductive layer of a photoelectric conversion device, from the view point of the relationship of the band gap with respect to the buffer layer and the window layer, the underlayer should preferably be constituted of a material that does not affect the band gap as much as possible. In the cases of the use application of the constituent films of the photoelectric conversion device, the difference between the band gap value of the transparent conductive layer and the band gap value of the underlayer should be preferably selected within the range of approximately 0 eV to approximately 0.15 eV. Therefore, the electrically conductive zinc oxide layered film in accordance with the present invention, wherein the coating film comprising the fine particles constituted of the same metal oxide as the metal oxide constituting the transparent conductive layer is formed as the underlayer, is advantageous in that the difference in band gap is selected within the range described above.

Also, the film formation with the coating technique is advantageous in that a large-scale film forming apparatus, or the like, is not necessary, in that the process is easy to perform, and in that the cost is kept low.

The process for producing this embodiment of the electrically conductive zinc oxide layered film will hereinbelow be described in detail.

In the process for producing this embodiment of the electrically conductive zinc oxide layered film, firstly, as illustrated in FIG. 2A, the substrate 10, at least the surface of the substrate 10 being electrically non-conductive, is prepared. In so far as at least the surface of the substrate 10 is electrically non-conductive, no limitation is particularly imposed upon the substrate 10. As illustrated in FIG. 2A, a glass substrate, a resin substrate, or the like, wherein the substrate itself is electrically non-conductive, may be used as the substrate 10. Alternatively, a layer comprising a substrate, and a plurality of layers, which have the electrically conductive characteristics and which are formed on the substrate, may be used as the substrate 10.

Thereafter, as illustrated in FIG. 2B, the underlayer 11, which comprises the plurality of the fine particles 11p, 11p, . . . containing electrically conductive zinc oxide as the principal ingredient, is formed on the surface of the substrate 10 by use of the coating technique.

A coating liquid used for the coating technique should preferably be such that the fine particles 11p, 11p, . . . are contained as densely as possible in a dispersion medium. The dispersion medium is not limited particularly. Examples of the dispersion media include solvents, such as water, various kinds of alcohols, methoxypropyl acetate, and toluene. Since the dispersion medium can be selected with the affinity for the substrate surface, and the like, being taken into consideration, the dispersion medium can cope with various surfaces having the electrically non-conductive characteristics and is thus preferable. For example, even on a surface of a layer comprising a window layer (i-ZnO) or a buffer layer (Zn(S,O,OH)) of a thin film solar cell having been formed on the surface, the underlayer 11 is formed easily by use of a dispersion medium selected with the affinity for the surface being taken into consideration.

In cases where no limitation is imposed particularly, as the solvent, water or an alcohol is preferable for small environmental load.

The fine particle concentration (solid concentration) in the coating liquid is not limited particularly and should be preferably selected within the range of 1% by mass to 50% by mass.

In so far as the electrically conductive zinc oxide fine particles 11p, 11p, . . . contain electrically conductive zinc oxide as the principal ingredient, no limitation is particularly imposed upon the electrically conductive zinc oxide fine particles 11p, 11p, . . . . However, the electrically conductive zinc oxide fine particles 11p, 11p, . . . should preferably contain, as the principal ingredient, at least one of the electrically conductive zinc oxides selected from the group consisting of boron-doped zinc oxide, aluminum-doped zinc oxide, and gallium-doped zinc oxide.

No limitation is particularly imposed upon the shapes of the electrically conductive zinc oxide fine particles 11p, 11p, . . . . Examples of the shapes of the electrically conductive zinc oxide fine particles 11p, 11p, . . . include a rod-like shape, a planar shape, and a spherical shape. Such that the crystal growth of the first electrically conductive zinc oxide thin film layer 12 proceeds uniformly over the entire area of the surface of the substrate 10 during the CBD technique performed at the subsequent stage, variations of the shapes and the sizes of the plurality of the fine particles 11p, 11p, . . . contained in the underlayer 11 should preferably be as small as possible.

A mean particle diameter of the plurality of the electrically conductive zinc oxide fine particles 11p, 11p, . . . is not limited particularly and may be of a size which does not exceed the total thickness of the layered film determined in accordance with the use application, and the like. The mean particle diameter of the plurality of the electrically conductive zinc oxide fine particles 11p, 11p, . . . constituting the underlayer 11 should preferably be equal to at least the size that sufficiently exhibits the effects as the nucleus of the crystal growth, the catalyst for the crystal growth, and the like. However, the mean particle diameter of the plurality of the electrically conductive zinc oxide fine particles 11p, 11p, . . . should preferably be as small as possible. Such that the crystal growth by the CBD technique performed as the subsequent stage is controlled appropriately, the mean particle diameter of the plurality of the electrically conductive zinc oxide fine particles 11p, 11p, . . . should be preferably selected within the range of 2 nm to 50 nm, and should be more preferably selected within the range of 2 nm to 40 nm.

No limitation is particularly imposed upon the density of the plurality of the electrically conductive zinc oxide fine particles 11p, 11p, . . . imparted onto the substrate 10. However, as described above, the density of the fine particles 11p, 11p, . . . in the underlayer 11 should preferably be as high as possible. If the density of the electrically conductive zinc oxide fine particles 11p, 11p, . . . in the underlayer 11 is markedly low, there is the risk that the effects as the nucleus of the crystal growth and/or the catalyst for the crystal growth, and the like, are not obtained sufficiently. As will be indicated later in the Examples in accordance with the present invention, the plurality of the electrically conductive zinc oxide fine particles 11p, 11p, . . . should preferably be imparted so as to cover the entire area of the surface of the substrate 10.

As will be described later in the Examples in accordance with the present invention, as the coating liquid, it is possible to use, for example, a commercially available electro-conductive zinc oxide PazetGK-40 dispersion (gallium-doped zinc oxide, dispersion medium: IPA (2-propanol), mean particle diameter: 20 nm to 40 nm, manufactured by Hakusuitech Ltd.) directly or after dilution.

No limitation is particularly imposed upon the technique for applying the coating liquid. Examples of the techniques for applying the coating liquid include a dipping technique wherein the substrate 10 is dipped in the fine particle dispersion, a spray coating technique, a dip coating technique, and a spin coating technique.

After the fine particle dispersion has been applied onto the substrate 10, the underlayer may be formed via a stage of removing the solvent from the coating layer. At this time, if necessary, heating processing may be performed.

Alternatively, the plurality of the electrically conductive zinc oxide fine particles 11p, 11p, . . . in a dry state may be obtained by performing heating processing on the fine particle dispersion and may be applied directly onto the substrate 10. In this manner, the underlayer 11 may be formed.

No limitation is particularly imposed upon the film thickness of the underlayer 11. Such that the crystal growth of the first electrically conductive zinc oxide thin film layer 12 by the CBD technique performed as the subsequent stage is controlled appropriately, the film thickness of the underlayer 11 should be preferably selected within the range of 2 nm to 1 μm. Also, such that the reaction for the formation of the first electrically conductive zinc oxide thin film layer 12 proceeds uniformly over the entire area of the surface of the substrate 10 during the CBD technique performed at the subsequent stage, the in-plane variation of the film thickness of the underlayer 11 should preferably be as small as possible.

Thereafter, as illustrated in FIG. 2C, the first electrically conductive zinc oxide thin film layer 12 is formed on the underlayer 11 by use of the CBD technique.

The first electrically conductive zinc oxide thin film layer 12 formed with the CBD technique is not limited particularly and should preferably contain boron-doped zinc oxide as the principal ingredient.

A reaction mixture used for the CBD technique should preferably contain zinc ions, nitrate ions, and at least one amine type borane compound (reducing agent). Examples of the amine type borane compounds include dimethylamine borane and trimethylamine borane. The reaction mixture should more preferably contain dimethylamine borane. An example of the reaction mixture is a reaction mixture containing zinc nitrate and dimethylamine borane.

In cases where the reaction mixture containing the zinc ions, the nitrate ions, and the amine type borane compound, such as dimethylamine borane, is used, the reaction conditions are not limited particularly. However, it is preferable to include a reaction stage in which the zinc ions and a complex formed from the aforesaid reducing agent coexist with each other.

The reaction temperature should be preferably selected within the range of 40° C. to 95° C., and should be more preferably selected within the range of 50° C. to 85° C. The reaction time may vary in accordance with the reaction temperature. The reaction time should be preferably selected within the range of 5 minutes to 72 hours, and should be more preferably selected within the range of 15 minutes to 24 hours. The pH conditions may be set such that at least a part of the underlayer 11 remains undissolved by the reaction mixture. In cases where the reaction mixture containing the zinc ions, the nitrate ions, and the amine type borane compound, such as dimethylamine borane, is used, the pH value of the reaction mixture at the stage from the beginning of the reaction to the completion of the reaction may be selected within the range of 3.0 to 8.0, and the metal oxide layer, such as ZnO, may thus be formed.

Principal reaction routes in the reaction mixture containing zinc nitrate and dimethylamine borane are thought to be as shown below.

Zn(NO₃)₂→Zn²⁺+2NO₃⁻ (1)

(CH₃)₂NHBH₃+H₂O→BO₂⁻+(CH₃)₂NH+7H⁺+6e⁻ (2)

NO₃⁻+H₂O+2e⁻→NO₂⁻+2OH⁻ (3)

Zn²⁺+2OH⁻→Zn(OH)₂ (4)

Zn(OH)₂→ZnO+H₂O (5)

As for the reaction described above, the reaction should preferably be performed under pH conditions such that the solubility of ZnO is low. Relationships among the values of pH, the kinds of various Zn-containing ions present in the reaction mixture, and the solubilities of the various Zn-containing ions are described in, for example, FIG. 7 of S. Yamabi and H. Imai, “Growth conditions for wurtzite zinc oxide films in aqueous solutions”, Journal of Materials Chemistry, Vol. 12, pp. 3773-3778, 2002. In the cases of the reaction described above, the solubility of ZnO is low within the pH range of 3.0 to 8.0, and the reaction proceeds appropriately within the aforesaid pH range. Specifically, in the cases of the reaction described above, the reaction proceeds appropriately under the mild pH conditions, which are not the strong acid or strong alkali conditions, and therefore the advantages are obtained in that little influence occurs on the substrate 10, and the like.

The reaction mixture containing the zinc ions, the nitrate ions, and the amine type borane compound, such as dimethylamine borane, may contain arbitrary ingredients other than the essential ingredients. The reaction mixture of the type described above may be of the aqueous type, does not require high reaction temperatures, and may be set under the mild pH conditions. Therefore, the reaction mixture of the type described above is preferable for a small environmental load.

In the manner described above, the underlayer 11, which comprises the plurality of the electrically conductive zinc oxide fine particles 11p, 11p, . . . , is formed on the surface of the substrate 10 by use of the coating technique, and the first electrically conductive zinc oxide thin film layer 12 is formed on the underlayer 11 by use of the CBD technique. The electrically conductive zinc oxide layered film 1, in which the underlayer 11 is approximately closely covered by the first electrically conductive zinc oxide thin film layer 12, is thus formed. (Reference may be made to the Examples, which will be described later.)

As will be indicated in the Examples, which will be described later, the electrically conductive zinc oxide layered film 1 is obtained as a layered film, in which the underlayer 11 is covered appropriately by the first electrically conductive zinc oxide thin film layer 12, and which has a sheet resistance value of as low as at most 4.0×10¹⁰Ω/□.

As described above, the electrically conductive zinc oxide layered film 1, which is the laminate comprising the underlayer 11 and the first electrically conductive zinc oxide thin film layer 12, is the film that is appropriate as the initial layer for the formation of a second electrically conductive zinc oxide thin film layer 13 with the electrolytic deposition technique (electrodeposition technique). Since the CBD technique is the electroless technique, the electrically conductive characteristics of the electrically conductive zinc oxide thin film which can be formed with the CBD technique is limited. Therefore, in order for an electrically conductive zinc oxide thin film, which has high electrically conductive characteristics adapted for use as the transparent conductive layer of the photoelectric conversion device, or the like, i.e. which has a low resistance, to be obtained, as illustrated in FIG. 2D, it is preferable to form the second electrically conductive zinc oxide thin film layer 13, which has a resistance decreased even further, by use of the electrodeposition technique with the first electrically conductive zinc oxide layered film 1 acting as the underlayer (initial layer).

In cases where an electrically conductive zinc oxide film is utilized as the transparent conductive layer, it is known that the transparency of the electrically conductive zinc oxide film is markedly affected by the quantity of pores, which are present at the surface or the inside region of the electrically conductive zinc oxide film, and the quantity of internal defects. As described above, at the surface of the electrically conductive zinc oxide layered film 1, the underlayer 11 is covered appropriately in a nearly unexposed state. Therefore, in cases where the second electrically conductive zinc oxide thin film layer 13 is formed with the electrodeposition technique by the utilization of the electrically conductive zinc oxide layered film 1 as the underlayer (initial layer), it is possible to form the electrically conductive zinc oxide layered film 2, which has a low resistance and good in-plane uniformity in resistance value and which is appropriate as the transparent conductive layer of the photoelectric conversion device.

The second electrically conductive zinc oxide thin film layer 13 should preferably contain low-resistance electrically conductive zinc oxide as the principal ingredient. As the low-resistance electrically conductive zinc oxide, as in the cases of the first electrically conductive zinc oxide thin film layer 12, boron-doped zinc oxide is preferable.

For the film formation of the second electrically conductive zinc oxide thin film layer 13, as the reaction mixture for the electrodeposition technique, it is possible to employ appropriately the reaction mixture identical with the reaction mixture described above with respect to the CBD technique.

As a preferable constitution of the electrodeposition technique, as will be indicated later in Example 2, there may be mentioned, for example, a technique wherein the substrate 10, on which the first electrically conductive zinc oxide thin film layer 12 has been formed with the CBD technique, is taken as a working electrode, wherein a zinc plate is taken as a counter electrode, wherein a silver/silver chloride electrode is used as a reference electrode, wherein the reference electrode is dipped in a saturated KCl solution, wherein connection to a reaction mixture is made with a salt bridge, and wherein the energizing processing is thereby performed. After the energizing processing has been performed, the substrate 10 is taken out from the reaction mixture and subjected to drying at the room temperature. In this manner, the second electrically conductive zinc oxide thin film layer 13 may be formed.

As for the reaction conditions appropriate for the electrodeposition technique, the reaction temperature should be preferably selected within the range of 25° C. to 95° C., and should be more preferably selected within the range of 40° C. to 90° C. If the reaction temperature is higher than 95° C., in cases where water is employed as the solvent, the solvent will evaporate. Conversely, if the reaction temperature is lower than 25° C., it will often occur that the reaction rate becomes low. The reaction time may vary in accordance with the reaction temperature. The reaction time should be preferably selected within the range of 1 to 60 minutes, and should be more preferably selected within the range of 1 to 30 minutes. In the cases of the electrodeposition technique, it is preferable to perform the energizing processing at 0.5 to 5 coulomb per 1 cm².

As described above under “Description of the Related Art,” the electrodeposition technique enables the high concentration doping of a dopant in the electrically conductive zinc oxide thin film. Therefore, the mean layer thickness d1 (nm) of the electrically conductive zinc oxide fine particle layer 11, the mean layer thickness d2 (nm) of the first electrically conductive zinc oxide thin film layer 12, which is formed on the electrically conductive zinc oxide fine particle layer 11, and the mean layer thickness d3 (nm) of the second electrically conductive zinc oxide thin film layer 13 should preferably satisfy the conditions of Formula (1) and Formula (2):

100≦d1+d2+d3(nm)≦2000 (1)

d1≦d2≦d3 (2)

In such cases, it is possible to form the electrically conductive zinc oxide layered film 2, which has a low resistance and which is appropriate as the transparent conductive layer of the photoelectric conversion device described later.

As will be indicated in the Examples and Table 1, which will be described later, the electrically conductive zinc oxide layered film 2 is obtained as a layered film, which had good transparency and a sheet resistance value of as low as 100Ω/□.

As described above, the electrically conductive zinc oxide layered film 1 in accordance with the present invention is formed on the substrate 10, at least the surface of the substrate 10 being electrically non-conductive, and comprises:

i) the electrically conductive zinc oxide fine particle layer 11, which is formed on the electrically non-conductive surface of the substrate 10, and which comprises at least one kind of the plurality of the fine particles 11p, 11p, . . . containing electrically conductive zinc oxide as the principal ingredient, and

ii) the first electrically conductive zinc oxide thin film layer 12, which is formed on the electrically conductive zinc oxide fine particle layer 11 that acts as the underlayer.

The electrically conductive zinc oxide thin film (layered film) 2 comprising the electrically conductive zinc oxide layered film 1 having the constitution described above enables the film formation to be performed with the liquid phase technique on the substrate, at least the surface of the substrate being electrically non-conductive, such that a metal layer need not be formed. The electrically conductive zinc oxide thin film (layered film) 2 having thus been formed appropriately covers the underlayer. Therefore, with the electrically conductive zinc oxide thin film (layered film) 2 in accordance with the present invention, the electrically conductive zinc oxide thin film (layered film) 2 that has a low resistance and that is thus appropriate as the transparent conductive layer (transparent electrode) is formed with the electrodeposition technique even on the substrate whose surface is electrically non-conductive, such as a layer provided with an electrically non-conductive layer, e.g. an electrical insulator layer, at the top surface.

### [Photoelectric Conversion Device]

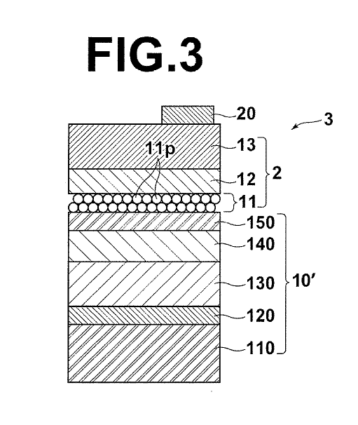

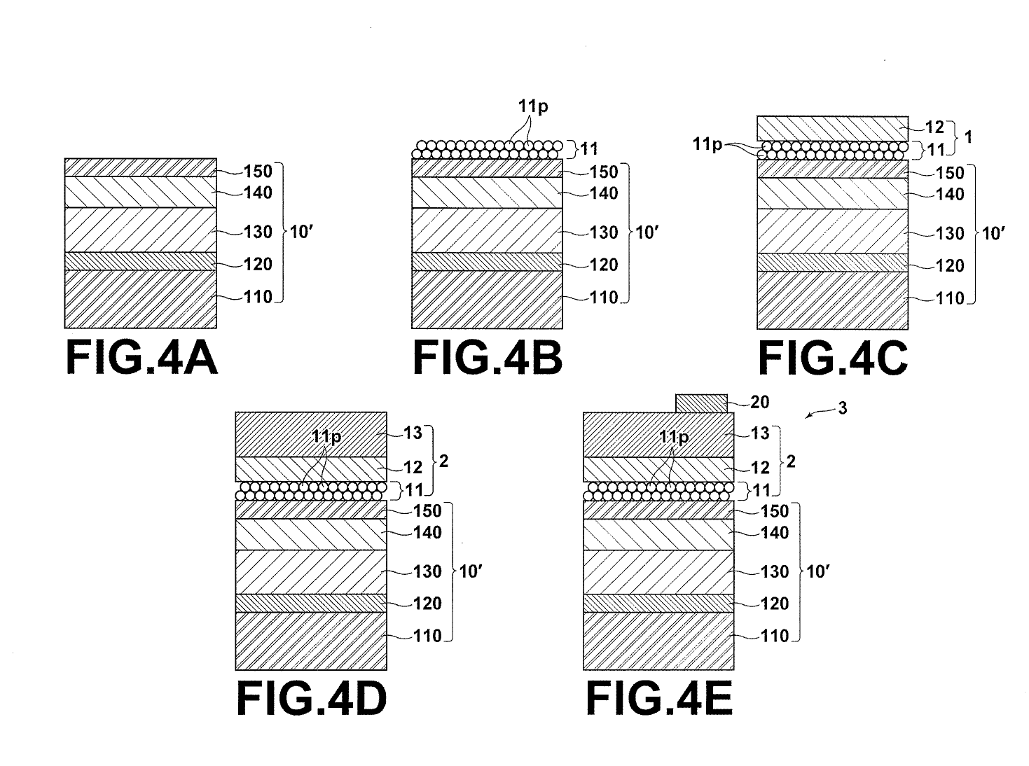

An embodiment of the photoelectric conversion device in accordance with the present invention will be described hereinbelow with reference to FIG. 3 and FIGS. 4A to 4E. FIG. 3 is a schematic sectional view showing a constitution of an embodiment of the photoelectric conversion device (solar cell) in accordance with the present invention. FIGS. 4A to 4E are schematic sectional views showing a process for producing the embodiment of the photoelectric conversion device (solar cell) of FIG. 3. For clearness, the scale, and the like, of each of the constituent elements are appropriately varied from the actual scale, and the like.

As illustrated in FIG. 3, the photoelectric conversion device (solar cell) 3 comprises a substrate 110 and layers stacked on the substrate 110. The layers stacked on the substrate 110 comprise a bottom electrode layer 120, a photoelectric conversion semiconductor layer 130 which generates positive hole-electron pairs through light absorption, a buffer layer 140, a protective layer (window layer) 150, a transparent conductive layer (transparent electrode) which is constituted of the aforesaid embodiment of the electrically conductive zinc oxide layered film 1 or 2, and a top electrode layer 20.

In FIG. 3, the substrate 10 of the aforesaid embodiment of the electrically conductive zinc oxide layered film 1 or 2, at least the surface of the substrate 10 being electrically non-conductive, is constituted of a layered substrate 10′ comprising the substrate 110 and the layers stacked on the substrate 110. The layers stacked on the substrate 110 comprise the bottom electrode layer 120, the photoelectric conversion semiconductor layer 130 which generates the positive hole-electron pairs through light absorption, the buffer layer 140, and the protective layer (window layer) 150. The constitution of the layered substrate 10′ will be described hereinbelow.

### (Substrate)

The constitution of the substrate 110 of the layered substrate 10′ is not limited particularly. By way of example, the substrate 110 may be constituted of a glass substrate. Alternatively, the substrate 110 may be constituted of a metal substrate, such as a stainless steel substrate, which is provided with an electrical insulator film on a surface. As another alternative, the substrate 110 may be constituted of an anodized substrate comprising: (a) an Al base material containing Al as a principal ingredient, and (b) an anodic oxide film containing Al₂O₃ as a principal ingredient, the anodic oxide film being formed on at least one surface side of the Al base material. As a further alternative, the substrate 110 may be constituted of an anodized substrate comprising: (a) a composite base material which is constituted of an Fe material containing Fe as a principal ingredient, and an Al material containing Al as a principal ingredient, the Al material being composited on at least one surface side of the Fe material, and (b) an anodic oxide film containing Al₂O₃ as a principal ingredient, the anodic oxide film being formed on at least one surface side of the composite base material. As a still further alternative, the substrate 110 may be constituted of an anodized substrate comprising: (a) a base material which is constituted of an Fe material containing Fe as a principal ingredient, and an Al film containing Al as a principal ingredient, the Al film being formed on at least one surface side of the Fe material, and (b) an anodic oxide film containing Al₂O₃ as a principal ingredient, the anodic oxide film being formed on at least one surface side of the base material. As another alternative, the substrate 110 may be constituted of a resin substrate, such as a polyimide resin substrate.

For the possibility of the production with successive stages, the substrate 110 should preferably be constituted of a flexible substrate, such as the metal substrate, which is provided with the electrical insulator film on the surface, the anodized substrate, or the resin substrate.

In cases where a coefficient of thermal expansion, heat resistance, electrical insulating characteristics of the substrate 110, and the like, are taken into consideration, the substrate 110 should particularly preferably be an anodized substrate selected from the group consisting of:

an anodized substrate comprising: (a) an Al base material containing Al as a principal ingredient, and (b) an anodic oxide film containing Al₂O₃ as a principal ingredient, the anodic oxide film being formed on at least one surface side of the Al base material,

an anodized substrate comprising: (a) a composite base material which is constituted of an Fe material containing Fe as a principal ingredient, and an Al material containing Al as a principal ingredient, the Al material being composited on at least one surface side of the Fe material, and (b) an anodic oxide film containing Al₂O₃ as a principal ingredient, the anodic oxide film being formed on at least one surface side of the composite base material, and

an anodized substrate comprising: (a) a base material which is constituted of an Fe material containing Fe as a principal ingredient, and an Al film containing Al as a principal ingredient, the Al film being formed on at least one surface side of the Fe material, and (b) an anodic oxide film containing Al₂O₃ as a principal ingredient, the anodic oxide film being formed on at least one surface side of the base material.

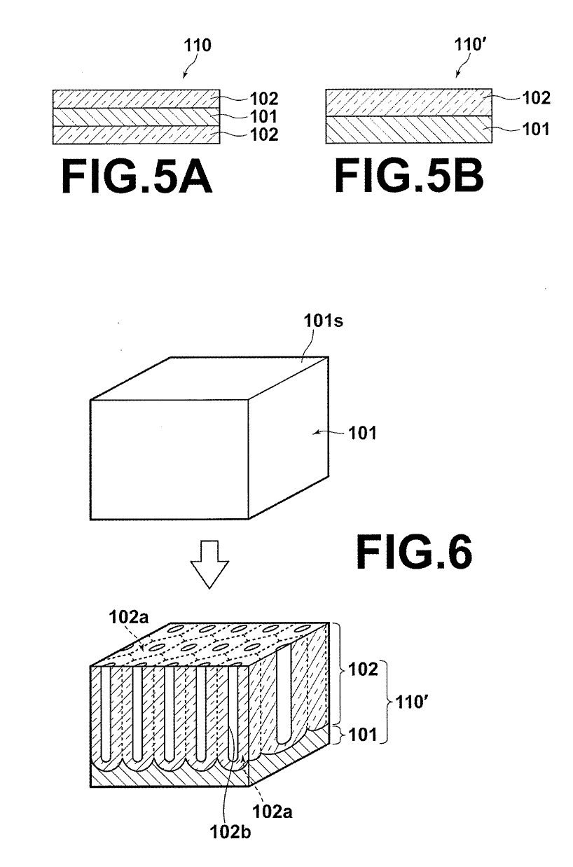

FIG. 5A is a schematic sectional view showing an example of a constitution of the anodized substrate 110. FIG. 5B is a schematic sectional view showing a different example of a constitution of an anodized substrate 110′.

The anodized substrate 110 (110′) is the substrate obtained by anodizing at least one surface side of an Al base material 101 containing Al as a principal ingredient. As illustrated in FIG. 5A, the anodized substrate may be the anodized substrate 110 comprising the Al base material 101, and the anodic oxide films 102, 102 formed on both surface sides of the Al base material 101. Alternatively, as illustrated in FIG. 5B, the anodized substrate may be the anodized substrate 110′ comprising the Al base material 101, and the anodic oxide film 102 formed on one surface side of the Al base material 101. The anodic oxide film 102 is the film containing Al₂O₃ as the principal ingredient.

In order for substrate warpage, which occurs due to a difference in coefficient of thermal expansion between Al and Al₂O₃, film peeling due to the substrate warpage, and the like, to be suppressed during device production stages, it is preferable to employ the anodized substrate 110 comprising the Al base material 101, and the anodic oxide films 102, 102 formed on both surface sides of the Al base material 101 as illustrated in FIG. 5A.

The anodizing processing may be performed in the manner described below. Specifically, if necessary, the Al base material 101 may be subjected to washing processing, polishing and smoothing processing, and the like. The Al base material 101 is then set as an anode and is immersed together with a cathode in an electrolyte. In this state, a voltage is applied between the anode and the cathode. The cathode may be constituted of carbon, aluminum, or the like. Also, no limitation is imposed upon the kind of the electrolyte. However, the electrolyte should preferably be an acidic electrolyte containing at least one kind of an acid selected from the group consisting of sulfuric acid, phosphoric acid, chromic acid, oxalic acid, sulfamic acid, benzenesulfonic acid, and amidosulfonic acid.

The anodizing conditions are not limited particularly and may vary in accordance with the kind of the electrolyte used. For example, the anodizing conditions should preferably be set such that the electrolyte concentration is selected within the range of 1% by mass to 80% by mass, the electrolyte temperature is selected within the range of 5° C. to 70° C., the electric current density is selected within the range of 0.005 A/cm² to 0.60 A/cm², the applied voltage is selected within the range of 1V to 200V, and the electrolysis time is selected within the range of 3 to 500 minutes.

As the electrolyte, it is preferable to employ sulfuric acid, phosphoric acid, oxalic acid, or a mixture of two or more of them. In cases where the electrolyte as described above is employed, the anodizing conditions should preferably be set such that the electrolyte concentration is selected within the range of 4% by mass to 30% by mass, the electrolyte temperature is selected within the range of 10° C. to 30° C., the electric current density is selected within the range of 0.05 A/cm² to 0.30 A/cm², and the applied voltage is selected within the range of 30V to 150V.

As illustrated in FIG. 6, in cases where the anodizing processing is performed on the Al base material 101 containing Al as the principal ingredient, the oxidation reaction advances from a surface 101s of the Al base material 101 toward the direction approximately normal to the surface 101s. The anodic oxide film 102 containing Al₂O₃ as the principal ingredient is formed in this manner. The anodic oxide film 102 having been formed with the anodizing processing has a structure, in which a plurality of fine pillar-shaped bodies 102a, 102a, . . . having approximately regular hexagon shapes, as viewed from above, are arrayed without a spacing being left among them. At an approximately middle area of each of the fine pillar-shaped bodies 102a, 102a, . . . , a fine hole 102b extending approximately straightly in the depth direction from the surface 101s is formed. Also, a bottom surface of each of the fine pillar-shaped bodies 102a, 102a, . . . has a round shape. Ordinarily, a barrier layer free from the fine hole 102b is formed at the bottom of each of the fine pillar-shaped bodies 102a, 102a, . . . . By the adjustment of the anodizing conditions, it is also possible to form the anodic oxide film 102 free from the fine holes 102b, 102b, . . . .

No limitation is particularly imposed upon the thickness of the Al base material 101 and the thickness of the anodic oxide film 102. In cases where the mechanical strength of the substrate 110′, the reduction of the thickness and the weight of the substrate 110′, and the like, are taken into consideration, the thickness of the Al base material 101 prior to the anodizing processing should be preferably selected within the range of, for example, 0.05 mm to 0.6 mm, and should be more preferably selected within the range of, for example, 0.1 mm to 0.3 mm. In cases where the electrically insulating characteristics of the substrate, the mechanical strength of the substrate, and the reduction of the thickness and the weight of the substrate are taken into consideration, the thickness of the anodic oxide film 102 should be preferably selected within the range of, for example, 0.1 μm to 100 μm.

### (Bottom Electrode Layer)

No limitation is particularly imposed upon the principal ingredient of the bottom electrode layer (rear surface electrode) 120. The principal ingredient of the bottom electrode layer 120 should preferably be Mo, Cr, W, or a combination of at least two of them. The principal ingredient of the bottom electrode layer 120 should more preferably be Mo. No limitation is imposed upon the film thickness of the bottom electrode layer (rear surface electrode) 120. The film thickness of the bottom electrode layer 120 should be preferably selected within the range of approximately 200 nm to approximately 1,000 nm.

### (Photoelectric Conversion Semiconductor Layer)

No limitation is particularly imposed upon the principal ingredient of the photoelectric conversion semiconductor layer 130. In order for a high photoelectric conversion efficiency to be obtained, the principal ingredient of the photoelectric conversion semiconductor layer 130 should preferably be at least one compound semiconductor having the chalcopyrite structure. The compound semiconductor having the chalcopyrite structure should more preferably be at least one compound semiconductor comprising a Group-Ib element, a Group-IIIb element, and a Group-VIb element.

The principal ingredient of the photoelectric conversion semiconductor layer 130 should preferably be at least one compound semiconductor comprising:

at least one of the Group-Ib elements selected from the group consisting of Cu and Ag,

at least one of the Group-IIIb elements selected from the group consisting of Al, Ga, and In, and

at least one of the Group-VIb elements selected from the group consisting of S, Se, and Te.

Examples of the aforesaid compound semiconductors include:

CuAlS₂, CuGaS₂, CuInS₂,

CuAlSe₂, CuGaSe₂

AgAlS₂, AgGaS₂, AgInS₂,

AgAlSe₂, AgGaSe₂, AgInSe₂,

AgAlTe₂, AgGaTe₂, AgInTe₂,

Cu(In,Al)Se₂, Cu(In,Ga)(S,Se)₂,

Cu_{1-z}In₁₋ₓGaₓSe_{2-y}S_{y}, wherein 0≦x≦1, 0≦y≦2, and 0≦z≦1 (CI(G)S),

Ag(In,Ga)Se₂, and Ag(In,Ga)(S,Se)₂.

No limitation is particularly imposed upon the film thickness of the photoelectric conversion semiconductor layer 130. The film thickness of the photoelectric conversion semiconductor layer 130 should be preferably selected within the range of 1.0 μm to 3.0 μm, and should be more preferably selected within the range of 1.5 μm to 2.0 μm.

### (Buffer Layer, Window Layer)

The buffer layer 140 is formed for the purposes of (1) prevention of recombination of photogenerated carriers, (2) matching of band discontinuity, (3) lattice matching, and (4) coverage of surface unevenness of the photoelectric conversion layer.

No limitation is particularly imposed upon the principal ingredient of the buffer layer 140. The buffer layer 140 should preferably contain a metal sulfide containing at least one of the metal elements selected from the group consisting of Cd, Zn, Sn, and In. The buffer layer 140 should preferably be formed with the CBD technique.

No limitation is particularly imposed upon the film thickness of the buffer layer 140. The film thickness of the buffer layer 140 should be preferably selected within the range of 10 nm to 2 μm, and should be more preferably selected within the range of 15 nm to 200 nm.

The window layer (protective layer) 150 is the intermediate layer for taking in light. In so far as the window layer 150 has the transparency for taking in the light, no limitation is particular imposed upon the window layer 150. With the band gap being taken into consideration, the composition of the window layer 30 should preferably be i-ZnO, or the like. No limitation is particularly imposed upon the film thickness of the window layer 150. The film thickness of the window layer 150 should be preferably selected within the range of 10 nm to 2 μm, and should be more preferably selected within the range of 15 nm to 200 nm. The photoelectric conversion device need not necessarily be provided with the window layer 150.

The layered substrate 10′ is constituted in the manner described above.

The transparent conductive layer (transparent electrode) 2 is the layer for taking in the light and acting as the electrode which pairs with the bottom electrode layer 120 so as to flow the electric current having been generated in the photoelectric conversion semiconductor layer 130.

In this embodiment of the photoelectric conversion device 3, as illustrated in FIGS. 4B to 4D, the transparent conductive layer 2 is constituted of the aforesaid embodiment of the electrically conductive zinc oxide layered film 2. As the transparent conductive layer 2, the electrically conductive zinc oxide layered film 2 comprising the electrically conductive zinc oxide fine particle layer 11, the first electrically conductive zinc oxide thin film layer 12, and the second electrically conductive zinc oxide thin film layer 13 is preferable for the low resistance. Alternatively, in lieu of the electrically conductive zinc oxide layered film 2, the electrically conductive zinc oxide layered film 1 comprising the electrically conductive zinc oxide fine particle layer 11 and the first electrically conductive zinc oxide thin film layer 12 may be employed as the transparent conductive layer.

As described above, with the aforesaid process for producing the electrically conductive zinc oxide layered film 1 (2) in accordance with the present invention, wherein the reaction is performed under the mild pH conditions, there is no risk that the substrate, and the like, will be damaged. The anodized substrate 110 (110′) employed in this embodiment has a comparatively low acid resistance and a comparatively low alkali resistance. However, with the aforesaid process for producing the electrically conductive zinc oxide layered film 1 (2) in accordance with the present invention, wherein the reaction is performed under the mild pH conditions, in cases where the anodized substrate 110 (110′) is used, there is no risk that the anodized substrate 110 (110′) will be damaged, and the photoelectric conversion device 3 having good quality is obtained. Therefore, in accordance with the present invention, the transparent electrode 2 having good transparency and good electrically conductive characteristics is obtained, such that the environmental load is small and such that little damage is given to the layered substrate 10′.

Finally, as illustrated in FIG. 4E, the top electrode (grid electrode) 20 is formed according to a pattern on the transparent conductive layer 2. No limitation is particularly imposed upon the principal ingredient of the top electrode 20. By way of example, the principal ingredient of the top electrode 20 may be Al. No limitation is particularly imposed upon the film thickness of the top electrode 20. The film thickness of the top electrode 20 should be preferably selected within the range of 0.1 μm to 3 μm.

This embodiment of the photoelectric conversion device 3 is produced in the manner described above.

The photoelectric conversion device 3 is adapted for use as the solar cell, or the like. The photoelectric conversion device 3 may further be provided with a cover glass, a protective film, or the like, as required, and may thus be constituted as the solar cell.

The electrically conductive zinc oxide layered film and the photoelectric conversion device in accordance with the present invention are not limited to the embodiments described above and may be embodied in various other ways.

### EXAMPLES

The present invention will further be illustrated by the following non-limitative examples.

### <Substrate>

As the substrate, a substrate 1 described below was prepared.

Substrate 1: The substrate 1 was constituted of a glass substrate (Micro Slide Glass, white edge polish, No. 2 S1112, manufactured by Matsunami Glass Ind., Ltd.).

### <Dispersion A of Electrically Conductive Zinc Oxide Fine Particles>

As a dispersion A, an electro-conductive zinc oxide PasetGK-40 dispersion (gallium-doped zinc oxide, dispersion medium: IPA (2-propanol), mean particle diameter: 20 nm to 40 nm, solid content: 20% by mass, manufactured by Hakusuitech Ltd.) was prepared.

### <Dispersion B of Zinc Oxide Fine Particles>

As a dispersion B of non-doped ZnO fine particles, a zinc oxide dispersion (trade name: NANOBYK-3840, dispersion medium: water, manufactured by BYK-Chemie GmbH) was prepared. The characteristics of the dispersion used were as follows: rod-shaped fine particles, sphere-equivalent mean particle diameter: 40 nm, solid content: 22% by mass.

### <Pre-Treatment for Imparting Metal Fine Particles>

The substrate was dipped in a mixed solution containing 1 g/L of SnCl₂.H₂O and 1 mL/L of 37% HCl. Thereafter, the substrate was dipped in a mixed solution containing 0.1 g/L of PdCl₂.H₂O and 0.1 moL/L of 37% HCl, and was then dried.

### <Reaction Mixture X (Zinc Nitrate-Dimethylamine Borane (DMAB)>

A volume of an aqueous 0.20M Zn (NO₃)₂ solution and an identical volume of an aqueous 0.10M DMAB solution were mixed together, and the resulting mixture was stirred for a period of time of at least 15 minutes. In this manner, a reaction mixture X (pH: approximately 5.5) to be used for the CBD technique was prepared.

### <Reaction Mixture Y (Zinc Nitrate-Dimethylamine Borane (DMAB)>

A volume of an aqueous 0.10M Zn (NO₃)₂ solution and an identical volume of an aqueous 0.10M DMAB solution were mixed together, and the resulting mixture was stirred for a period of time of at least 15 minutes. In this manner, a reaction mixture Y (pH: approximately 5.8) to be used for the electrodeposition technique was prepared.

### Example 1

The aforesaid dispersion A of the electrically conductive zinc oxide fine particles was applied onto the substrate 1 with the spin coating technique (number of revolution: 1,000 rpm, rotation time: 30 seconds). The resulting coating layer was dried at the room temperature, and an electrically conductive zinc oxide fine, particle layer was thus formed on the substrate 1.

Thereafter, a ZnO layer was grown on the thus formed electrically conductive zinc oxide fine particle layer with the CBD technique. Specifically, the substrate 1, on which the electrically conductive zinc oxide fine particle layer had been formed, was dipped in 50 mL of the reaction mixture X, which had been adjusted at a temperature of 85° C., for 24 hours. Thereafter, the substrate 1 was taken out from the reaction mixture X and dried at the room temperature. In this manner, a first electrically conductive zinc oxide thin film layer was formed on the electrically conductive zinc oxide fine particle layer. The pH value of the reaction mixture X prior to the beginning of the reaction was equal to 5.43, and the pH value of the reaction mixture X after the completion of the reaction was equal to 6.26.

### Example 2

The first electrically conductive zinc oxide thin film layer was formed on the substrate 1 with the CBD technique in the same manner as that in Example 1. Thereafter, a second electrically conductive zinc oxide thin film layer was formed on the first electrically conductive zinc oxide thin film layer with the electrodeposition technique by use of the reaction mixture Y. In the electrodeposition technique, the substrate 1, on which the first electrically conductive zinc oxide thin film layer had been formed with the CBD technique, was utilized as the working electrode. Also, a zinc plate was utilized as a counter electrode. Further, a silver/silver chloride electrode was utilized as the reference electrode.

Specifically, the reference electrode was dipped in a saturated KCl solution, and connection to the reaction mixture Y adjusted at a temperature of 60° C. was made with a salt bridge. In this state, energizing processing at 4 coulomb per 1 cm² was performed for 30 minutes. Thereafter, the substrate 1 was taken out from the reaction mixture Y and was dried at the room temperature. In this manner, the second electrically conductive zinc oxide thin film layer was formed.

### Example 3

A first electrically conductive zinc oxide thin film layer was formed basically in the same manner as that in Example 1. At this time, the dispersion A was diluted by a factor of 10, and the resulting dispersion was applied with the spin coating technique under the same conditions as those in Example 1.

### Comparative Example 1

An electrically conductive zinc oxide thin film layer was formed in the same manner as that in Example 1, except that the formation of the first electrically conductive zinc oxide thin film layer with the CBD technique was not performed.

### Comparative Example 2

A first electrically conductive zinc oxide thin film layer was formed in the same manner as that in Example 1, except that the dispersion B was used in lieu of the dispersion A. As a result, the first electrically conductive zinc oxide thin film layer, whose sheet resistance value was capable of being measured, was capable of being formed, but a layer uniformly covering the underlayer was not obtained.

### Comparative Example 3

Metal fine particles were imparted onto the substrate 1 by performing pre-treatment. Thereafter, a first electrically conductive zinc oxide thin film layer was formed on the metal fine particles by use of the CBD technique. The conditions for the CBD technique were identical with the conditions in Example 1.

The principal production conditions in each example and the results of the measurement of the sheet resistance value are shown in Table 1. The sheet resistance value was measured by use of a high resistivity meter (Hirester IP, MCP-HT260, manufactured by Mitsubishi Chemical Corporation) or a low resistivity meter (Lorester GP, MCP-T610, manufactured by Mitsubishi Chemical Corporation).

As indicated in Table 1, the effectiveness of the present invention was confirmed.

TABLE 1

| | Example 1 | Example 2 | Example 3 |
|---|---|---|---|
| Fine particle layer | ZnO:Ga fine | ZnO:Ga fine | ZnO:Ga fine |
| | particles | particles | particles |
| Thickness of fine particle layer (nm) | 120 | 120 | 80 |
| Mean value of primary particle diameters (nm) | 20 to 40 | 20 to 40 | 20 to 40 |
| Kind of first electrically conductive zinc oxide | ZnO:B | ZnO:B | ZnO:B |
| thin film layer formed with CBD technique | | | |
| Thickness of first electrically conductive zinc | 480 | 480 | 200 |
| oxide thin film layer formed with CBD technique (nm) | | | |
| Kind of second electrically conductive zinc oxide | — | ZnO:B | — |
| thin film layer formed with electrolytic deposition | | | |
| technique | | | |
| Thickness of second electrically conductive zinc | — | 1000 | — |
| oxide thin film layer formed with electrolytic | | | |
| deposition technique (nm) | | | |
| Thickness of layered film (nm) | 600 | 1600 | 280 |
| Sheet resistance (Ω/□) | 5.6 × 10⁷ | 1.0 × 10² | 9.0 × 10⁹ |
| | Comparative | Comparative | Comparative |
| | Example 1 | Example 2 | Example 3 |
| Fine particle layer | ZnO:Ga fine | Non-doped ZnO | Metal fine |
| | particles | fine particles | particles |
| Thickness of fine particle layer (nm) | 120 | 190 | 20 |
| Mean value of primary particle diameters (nm) | 20 to 40 | 20 to 40 | 1 to 5 |
| Kind of first electrically conductive zinc oxide | — | ZnO:B | ZnO:B |
| thin film layer formed with CBD technique | | | |
| Thickness of first electrically conductive zinc | — | 130 | 190 |
| oxide thin film layer formed with CBD technique (nm) | | | |
| Kind of second electrically conductive zinc oxide | — | — | — |
| thin film layer formed with electrolytic deposition | | | |
| technique | | | |
| Thickness of second electrically conductive zinc | — | — | — |
| oxide thin film layer formed with electrolytic | | | |
| deposition technique (nm) | | | |
| Thickness of layered film (nm) | 120 | 320 | 210 |
| Sheet resistance (Ω/□) | 1.3 × 10¹¹ | 3.4 × 10¹¹ | 7.8 × 10¹⁰ |

### INDUSTRIAL APPLICABILITY

The electrically conductive zinc oxide layered film in accordance with the present invention and the photoelectric conversion device comprising the electrically conductive zinc oxide layered film are appropriately applicable to use applications of, for example, photoelectric conversion devices for use in solar cells, infrared sensors, and the like.

What is claimed is:

1. An electrically conductive zinc oxide layered film having been formed on a substrate, at least a surface of the substrate being electrically non-conductive,
the electrically conductive zinc oxide layered film comprising:
i) an electrically conductive zinc oxide fine particle layer, which is formed on the electrically non-conductive surface of the substrate, and which comprises at least one kind of a plurality of fine particles containing electrically conductive zinc oxide as a principal ingredient, and
ii) an electrically conductive zinc oxide thin film layer, which is formed on the electrically conductive zinc oxide fine particle layer.

2. An electrically conductive zinc oxide layered film as defined in claim 1 wherein a mean particle diameter of the plurality of the fine particles constituting the electrically conductive zinc oxide fine particle layer is selected within the range of 1 nm to 50 nm.

3. An electrically conductive zinc oxide layered film as defined in claim 1 wherein the plurality of the fine particles constituting the electrically conductive zinc oxide fine particle layer contains, as a principal ingredient, at least one of the electrically conductive zinc oxides selected from the group consisting of boron-doped zinc oxide, aluminum-doped zinc oxide, and gallium-doped zinc oxide.

4. An electrically conductive zinc oxide layered film as defined in claim 1 wherein the electrically conductive zinc oxide thin film layer, which is formed on the electrically conductive zinc oxide fine particle layer, contains boron-doped zinc oxide as a principal ingredient.

5. An electrically conductive zinc oxide layered film as defined in claim 1 wherein the electrically conductive zinc oxide thin film layer, which is formed on the electrically conductive zinc oxide fine particle layer, is taken as a first electrically conductive zinc oxide thin film layer, and
the electrically conductive zinc oxide layered film further comprises a second electrically conductive zinc oxide thin film layer, which is formed with an electrolytic deposition technique on the first electrically conductive zinc oxide thin film layer.

6. An electrically conductive zinc oxide layered film as defined in claim 5 wherein a mean layer thickness d1 (nm) of the electrically conductive zinc oxide fine particle layer, a mean layer thickness d2 (nm) of the first electrically conductive zinc oxide thin film layer, which is formed on the electrically conductive zinc oxide fine particle layer, and a mean layer thickness d3 (nm) of the second electrically conductive zinc oxide thin film layer satisfy the conditions of Formula (1) and Formula (2):
100≦d1+d2+d3(nm)≦2000 (1)
d1≦d2≦d3 (2)

7. An electrically conductive zinc oxide layered film as defined in claim 5 wherein the electrically conductive zinc oxide layered film has a sheet resistance value of at most 4.0×10¹⁰Ω/□.

8. An electrically conductive zinc oxide layered film as defined in claim 5 wherein the second electrically conductive zinc oxide thin film layer contains boron-doped zinc oxide as a principal ingredient.

9. A photoelectric conversion device, comprising a bottom electrode layer, a photoelectric conversion semiconductor layer, a buffer layer, and a transparent conductive layer, which are stacked in this order on a substrate,
wherein the transparent conductive layer is formed on the buffer layer, and
the transparent conductive layer comprises:
i) an electrically conductive zinc oxide fine particle layer, which is formed on a surface of the buffer layer or on a surface of an electrically non-conductive thin film layer formed on the buffer layer, and which comprises at least one kind of a plurality of fine particles containing electrically conductive zinc oxide as a principal ingredient, and
ii) an electrically conductive zinc oxide thin film layer, which is formed on the electrically conductive zinc oxide fine particle layer.

10. A photoelectric conversion device as defined in claim 9 wherein a mean particle diameter of the plurality of the fine particles constituting the electrically conductive zinc oxide fine particle layer is selected within the range of 1 nm to 50 nm.

11. A photoelectric conversion device as defined in claim 9 wherein the plurality of the fine particles constituting the electrically conductive zinc oxide fine particle layer contains, as a principal ingredient, at least one of the electrically conductive zinc oxides selected from the group consisting of boron-doped zinc oxide, aluminum-doped zinc oxide, and gallium-doped zinc oxide.

12. A photoelectric conversion device as defined in claim 9 wherein the electrically conductive zinc oxide thin film layer, which is formed on the electrically conductive zinc oxide fine particle layer, contains boron-doped zinc oxide as a principal ingredient.

13. A photoelectric conversion device as defined in claim 9 wherein the electrically conductive zinc oxide thin film layer, which is formed on the electrically conductive zinc oxide fine particle layer, is taken as a first electrically conductive zinc oxide thin film layer, and
the transparent conductive layer further comprises a second electrically conductive zinc oxide thin film layer, which is formed with an electrolytic deposition technique on the first electrically conductive zinc oxide thin film layer.

14. A photoelectric conversion device as defined in claim 13 wherein a mean layer thickness d1 (nm) of the electrically conductive zinc oxide fine particle layer, a mean layer thickness d2 (nm) of the first electrically conductive zinc oxide thin film layer, which is formed on the electrically conductive zinc oxide fine particle layer, and a mean layer thickness d3 (nm) of the second electrically conductive zinc oxide thin film layer satisfy the conditions of Formula (1) and Formula (2):
100≦d1+d2+d3(nm)≦2000 (1)
d1≦d2≦d3 (2)

15. A photoelectric conversion device as defined in claim 13 wherein the transparent conductive layer has a sheet resistance value of at most 4.0×10¹⁰Ω/□.

16. A photoelectric conversion device as defined in claim 13 wherein the second electrically conductive zinc oxide thin film layer contains boron-doped zinc oxide as a principal ingredient.

17. A photoelectric conversion device as defined in claim 9 wherein the buffer layer contains a metal sulfide containing at least one of the metal elements selected from the group consisting of Cd, Zn, Sn, and In.

18. A photoelectric conversion device as defined in claim 9 wherein a principal ingredient of the photoelectric conversion semiconductor layer is at least one compound semiconductor having a chalcopyrite structure.

19. A photoelectric conversion device as defined in claim 9 wherein a principal ingredient of the photoelectric conversion semiconductor layer is at least one compound semiconductor comprising:
at least one of the Group-Ib elements selected from the group consisting of Cu and Ag,
at least one of the Group-IIIb elements selected from the group consisting of Al, Ga, and In, and
at least one of the Group-VIb elements selected from the group consisting of S, Se, and Te.

20. A photoelectric conversion device as defined in claim 9 wherein the substrate is an anodized substrate selected from the group consisting of:
an anodized substrate comprising: (a) an Al base material containing Al as a principal ingredient, and (b) an anodic oxide film containing Al₂O₃ as a principal ingredient, the anodic oxide film being formed on at least one surface side of the Al base material,
an anodized substrate comprising: (a) a composite base material which is constituted of an Fe material containing Fe as a principal ingredient, and an Al material containing Al as a principal ingredient, the Al material being composited on at least one surface side of the Fe material, and (b) an anodic oxide film containing Al₂O₃ as a principal ingredient, the anodic oxide film being formed on at least one surface side of the composite base material, and
an anodized substrate comprising: (a) a base material which is constituted of an Fe material containing Fe as a principal ingredient, and an Al film containing Al as a principal ingredient, the Al film being formed on at least one surface side of the Fe material, and (b) an anodic oxide film containing Al₂O₃ as a principal ingredient, the anodic oxide film being formed on at least one surface side of the base material.

21. A solar cell, comprising a photoelectric conversion device as defined in claim 9.
